(19) United States
(12) Patent Application Publication
(10) Pub. No.: US 2026/0343806 A1
(43) Pub. Date: Oct. 29, 2026

(54) COMPUTING DEVICE HEAT DISTRIBUTION USING FLUID CHANNELS

(71) Applicant: Microsoft Technology Licensing, LLC, Redmond, WA (US)

(72) Inventors: Sneha Rajeev SONDUR, Redmond, WA (US); Alan HSIAO, Bellevue, WA (US); Mark Troy LINK, Spokane, WA (US); Hector James WILSON, Seattle, WA (US)

(73) Assignee: Microsoft Technology Licensing, LLC, Redmond, WA (US)

(21) Appl. No.: 19/189,098

(22) Filed: Apr. 24, 2025

(51) Int. Cl. H05K 7/20; G06F 1/20

(52) U.S. Cl. CPC H05K 7/20272; G06F 1/20; H05K 7/20281; G06F 2200/201

(57) ABSTRACT

A computing device includes a processing component that generates heat during operation, and a device housing component proximate to the processing component, such that the device housing component is heated by the processing component. A plurality of fluid channels is thermally coupled with the device housing component. A fluid pump is configured to circulate cooling fluid through the plurality of fluid channels in the device housing component, such that the cooling fluid facilitates heat distribution across the device housing component.

### BACKGROUND

Computing devices include various internal components that generate heat during operation. As computing devices continue to become more capable, the increased functionality often results in higher thermal output from the device’s internal processing components.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

A computing device includes a processing component that generates heat during operation, and a device housing component proximate to the processing component, such that the device housing component is heated by the processing component. A plurality of fluid channels are thermally coupled with the device housing component. A fluid pump is configured to circulate cooling fluid through the plurality of fluid channels in the device housing component, such that the cooling fluid facilitates heat distribution across the device housing component.

### BRIEF DESCRIPTION OF THE DRAWINGS

FIGS. 1A and 1B schematically depict an example computing device including a processing component that generates heat during operation.

FIGS. 2A-2C schematically depict the use of a plurality of fluid channels of a computing device to circulate cooling fluid.

FIG. 3 schematically depicts a film layer affixed to a device housing component, with a plurality of fluid channels formed in the film layer.

FIG. 4 schematically depicts a plurality of fluid conduits embedded in a plurality of fluid channels of a device housing component.

FIG. 5 schematically shows a cross-sectional view of an example device housing component including a fluid sealing layer used to enclose a fluid channel.

FIG. 6 schematically shows a cross-sectional view of an example computing device including a plurality of fluid channels formed in a mid-frame.

FIG. 7 schematically depicts another example computing device including a display portion and an input portion.

FIG. 8 schematically depicts an example computing device including two separate sets of fluid channels through which cooling fluid is circulated.

FIG. 9 schematically depicts an example computing device including an active cooling system.

FIG. 10 illustrates an example method for heat distribution in a computing device.

FIG. 11 schematically shows an example computing system.

### DETAILED DESCRIPTION

Computing devices often include internal components that generate heat during operation. These may include, for instance, computer processors, display hardware, communication interfaces, artificial intelligence (AI) processing components, systems-on-a-chip (SOCs), etc. In some device form factors, such as laptops, smartphones, tablets, wearable devices, etc., it can be difficult to effectively dissipate this heat, due to the limited available space for thermal management components like heat sinks, fans, vapor chambers, etc. As a result, heat may accumulate in localized areas, creating thermal gradients that adversely affect component performance, system reliability, and/or user comfort. For instance, proximity between internal heat-generating components and a device’s external housing can form a localized hot spot on the device’s exterior. If the temperature of this hot spot exceeds a predefined threshold, then the device’s processing components may be throttled to produce less heat, therefore reducing the temperature of the hot spot. This can improve user comfort (e.g., ensuring the device is not uncomfortably hot for the user to touch), although it reduces the computational performance of the device. In other words, in some scenarios, a device’s external surface temperature may serve as a limiting factor for device performance.

Accordingly, the present disclosure describes example arrangements useable to distribute heat throughout a device housing component of a computing device. Specifically, as described herein, a computing device includes at least one processing component that generates heat during operation, and a device housing component that is heated by the processing component. A plurality of fluid channels are thermally coupled to the device housing component, and a fluid pump is configured to circulate cooling fluid through the plurality of fluid channels. Circulation of the cooling fluid facilitates heat distribution across the device housing component, thereby increasing thermal uniformity. In other words, this may have the effect of distributing heat from a localized hot spot throughout the surface area of the device housing component, which reduces the thermal gradient across the housing. This can beneficially reduce or alleviate the need for other cooling systems, and may therefore enable a reduction in the bulk, complexity, and/or cost of the computing device. Furthermore, integrating the fluid channels into the device housing can facilitate improved space efficiency for the computing device, as compared to scenarios where the fluid channels are directly coupled with the processing components.

By actively circulating a cooling fluid through fluid channels thermally coupled to the housing, heat can be spread laterally across a broader surface area. This mitigates the formation of hot spots, reduces thermal stress on localized components, and may improve the operating efficiency and longevity of the processing components. Furthermore, because the fluid channels are integrated into structural elements of the device, this approach beneficially supports effective thermal management without compromising device form factor or increasing noise. Furthermore, as discussed above, throttling may in some cases be applied based on the temperature of a hot spot on the device’s surface. Because the arrangements described herein may serve to reduce the hot spot temperature, less throttling can be applied to the device’s processing components, thereby contributing to an increase in the device’s computational performance for the same external surface temperature. For instance, in one example scenario, a two-degree reduction in the external hotspot temperature can enable a 10% performance improvement.

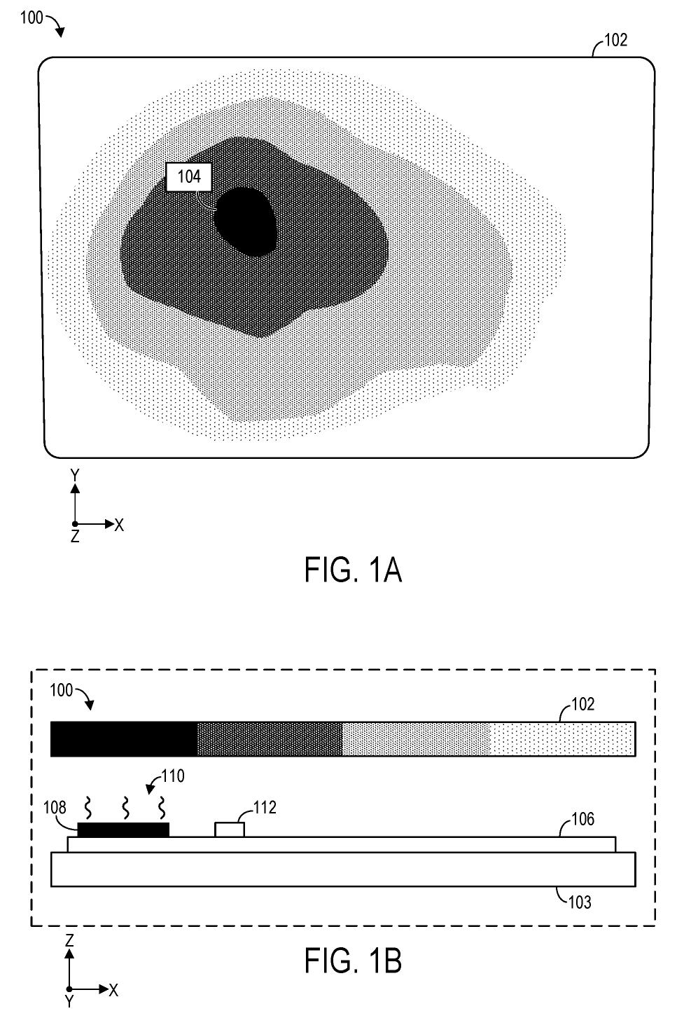

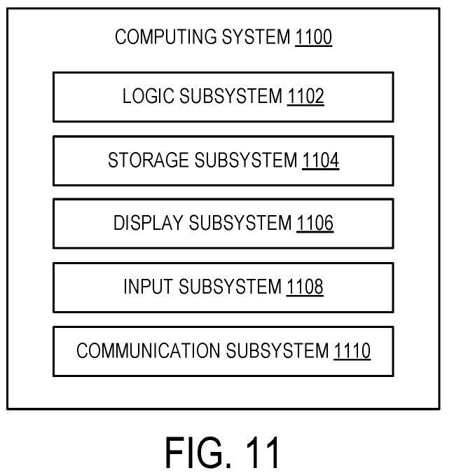

FIG. 1A schematically depicts a portion of an example computing device 100, taking the form of a portable computing device, such as a smartphone or tablet. It will be understood that the specific appearance of computing device 100 is non-limiting and highly-simplified, and provided only for the sake of explanation. Because portable computing devices often have compact form factors that can complicate effective thermal management, the techniques described herein may be particularly advantageous for such devices, including smartphones, tablets, laptops, wearable devices, portable gaming devices, etc. For instance, in the design of such devices, it may be desirable to avoid using bulky internal cooling systems for thermal management, while still managing the temperature of the device’s external surface. However, it will be understood that the arrangements and techniques described herein may be applicable to any suitable computing devices, each having any suitable capabilities, hardware configurations, and form factors. In some examples, a computing device as described herein may be implemented as computing system 1100 described below with respect to FIG. 11.

As shown, computing device 100 includes a device housing component 102. In this example, the device housing component is an external housing of the computing device. It will be understood that, in other examples, the term "device housing component" may apply to other suitable components of the computing device in addition to, or instead of, an external housing. As examples, these may include internal structural elements such as a mid-frame, chassis, internal support bracket, and/or other thermally conductive structural members configured to provide mechanical support or enclosure within the device. The device housing component may be formed from any suitable materials, such as metals, polymers, composite materials, and/or a combination thereof.

In the example of FIG. 1A, the computing device includes one or more internal processing components that generate heat during operation. As such, the device housing component is heated by the processing component. This is illustrated in FIG. 1A, in which shading patterns are used to indicate the relative temperature of different portions of the device housing portion, with darker shading patterns representing higher temperatures. As shown, heat generated by the processing component contributes to a localized hot spot 104 on the external surface of the device housing component. As discussed above, such a hot spot can potentially impact user comfort while the device is used, as high temperatures on the device’s exterior can make the device less comfortable for a user to hold or touch.

Though not shown in FIG. 1A, it will be understood that the computing device may include any of a wide variety of suitable components, such as a display, user input mechanisms (e.g., touch sensors, buttons, switches), sensors, output mechanisms (e.g., speakers, haptic feedback components), and/or various communication interfaces, as examples. The display may include, for example, a liquid crystal display (LCD), organic light-emitting diode (OLED) display, or other suitable display technologies. User input mechanisms may be integrated into the display surface in the form of a capacitive touch panel, and/or may be provided separately. The device may include a battery, storage media, wireless communication circuitry, one or more microphones, imaging sensors such as front- or rear-facing cameras, etc. While the present disclosure primarily focuses on redistributing heat generated by processing components, this is non-limiting, and it will be understood that any of a wide variety of hardware components may generate heat during use. For instance, in some examples, a computing device may include power delivery/regulation components, and/or a wireless charging coil, which also may generate heat. The techniques described herein may in some cases be applied to redistribute such heat throughout the device housing, as will be discussed in more detail below. These and other components may be positioned within or supported by the device housing component, and may operate in coordination with the processing component to enable the desired functionality of the computing device. The specific arrangement of components may vary depending on the intended form factor and functionality of the device.

FIG. 1B shows a cross-sectional view of aspects of computing device 100, including the device housing component 102. An opposing device housing component 103 forms an opposite external surface of the device. Within the device interior, between the device housing component 102 and opposing housing component 103, computing device 100 includes a printed circuit board (PCB) 106 to which a processing component 108 is communicatively coupled. The processing component is generating heat 110 during operation, which affects the temperature of the device housing component 102, as shown. The portion of the device housing component that is closest to the processing component has the highest temperature, while the temperature drops as the distance from the processing component increases, thereby forming a thermal gradient across the device housing component. It will be understood that heat generated by the processing component may additionally affect other components of computing device 100, although this is not represented in FIG. 1A for the sake of simplicity.

Additionally, in FIG. 1A, the computing device includes a temperature sensor 112. The temperature sensor may output a measured temperature of the internal environment of the computing device. In some examples, measurements output by temperature sensor 112, and/or other temperature sensors of the computing device, may be used to infer the temperature of the hotspot on the device’s exterior. For instance, measurements output by temperature sensor 112 may be input to an algorithm that estimates the temperature of the exterior hotspot, based on a relationship derived from prior thermal testing of the computing device. In some examples, the computing device may include one or more temperature sensors configured to directly measure the temperature of the device housing component – e.g., such sensors may be positioned at different locations at which hot spots tend to form. It will be understood that a computing device may have any suitable number of temperature sensors, each of which may be implemented in any suitable way, and have any suitable position on or within the computing device. Furthermore, as will be described in more detail below, temperature measurements output by temperature sensors may be used to activate and/or regulate the operation of a fluid pump used to circulate cooling fluid for thermal management.

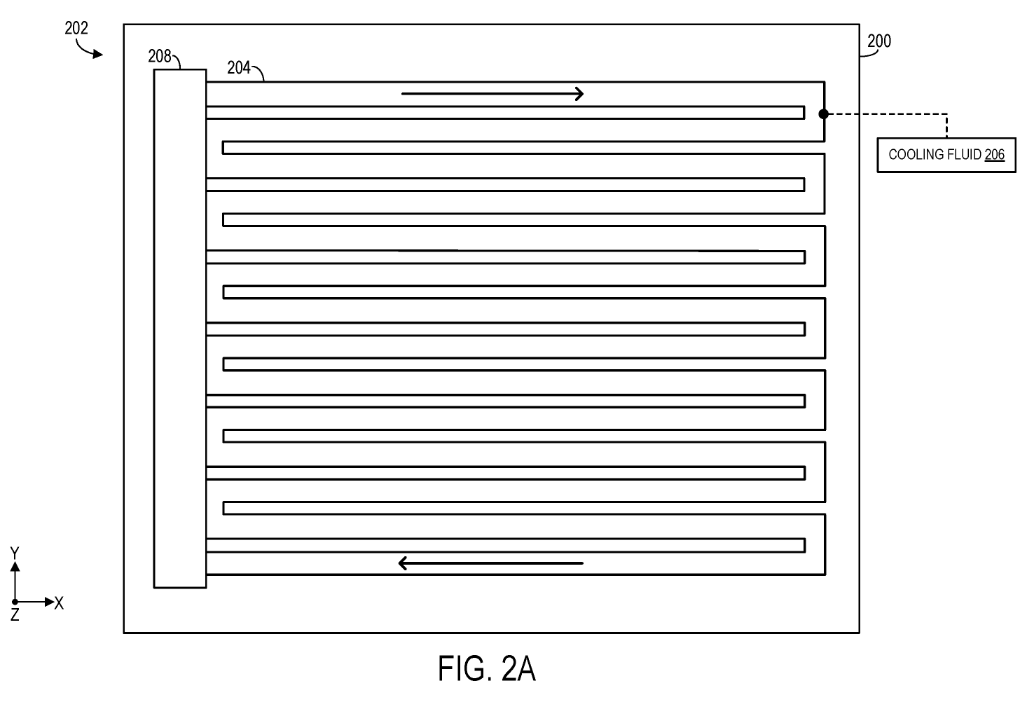

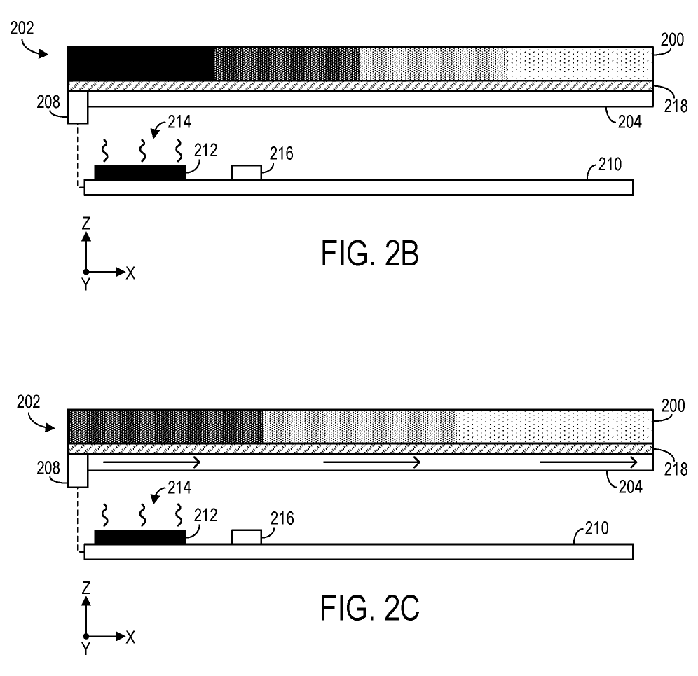

As discussed above, the external temperature of the computing device can sometimes be a limiting factor in the device’s computational performance, in cases where the device’s processing components are throttled in order to reduce the device’s external temperature. Accordingly, FIG. 2A schematically illustrates a device housing component 200 of another example computing device 202. In this example, the computing device includes arrangements useable to distribute heat across the device housing component, as will be described in more detail below. As with computing device 100, it will be understood that the specific appearance of computing device 202 is non-limiting and highly simplified for the sake of explanation. Furthermore, it will be understood that computing device 202 may include any of a wide range of various suitable components not shown in FIG. 2A.

In this example, the device housing component is a portion of the device’s chassis that separates the interior of the computing device from the external environment, and FIG. 2A shows an interior-facing surface of the device housing component. In other words, at least some of the features depicted in FIG. 2A are located within the interior of the computing device. This includes a plurality of fluid channels 204, which are thermally coupled with the device housing component 200. The computing device includes cooling fluid 206 within the plurality of cooling channels. Additionally, the computing device includes a fluid pump configured to circulate the cooling fluid through the plurality of fluid channels in the device housing component. In this manner, the cooling fluid facilitates heat distribution across the device housing component.

As used herein, the term "fluid channel" refers to any suitable passage, conduit, groove, or cavity through which a cooling fluid may flow. A fluid channel may be formed in or on a structural component of the electronic device, such as a housing, mid-frame, or thermally conductive film layer. The fluid channel may be enclosed to define a flow path, or may be open and subsequently enclosed by another layer or structure. Fluid channels may be formed using a variety of manufacturing techniques, including but not limited to subtractive methods (e.g., machining) and additive methods (e.g., 3D printing). The cross-sectional shape, dimensions, and routing of the fluid channels may vary depending on thermal management objectives and space constraints. In the example of FIG. 2A, fourteen parallel fluid channels are used, and each of the fluid channels are connected, such that they collectively form a continuous volume. However, it will be understood that the specific arrangement of fluid channels shown in FIG. 2A is non-limiting.

In some examples, the fluid channels may be integrally formed within the housing component itself, such as by machining or additive manufacturing techniques, resulting in direct thermal conduction between the housing material and the cooling fluid. In other examples, the fluid channels may be formed in a separate film or laminate structure that is affixed to a surface of the housing component, such as an interior-facing surface. In such cases, the film may be constructed from a thermally conductive material and secured using a thermally conductive adhesive or bonding layer to maintain efficient thermal coupling. Additional layers or sealing structures may be provided to enclose the fluid channels and prevent leakage, while preserving the desired thermal relationship with the housing component. The configuration may be selected based on factors such as manufacturing constraints, material selection, desired thermal performance, and/or space availability within the device enclosure.

As used herein, the term "cooling fluid" refers to any suitable substance useable to absorb and transfer heat away from components within an electronic device to facilitate thermal management. The cooling fluid may be characterized by properties such as high thermal capacity, low viscosity, chemical stability, and/or non-corrosiveness to ensure efficient heat transfer and compatibility with device materials. Examples of cooling fluids include, but are not limited to, water, deionized water, glycol-based fluids, synthetic oils, etc. The selection of a particular cooling fluid may depend on factors such as the operating temperature range, thermal conductivity requirements, electrical insulation needs, and compatibility with device materials.

As used herein, the term "fluid pump" refers to a device configured to induce movement of a cooling fluid through one or more fluid channels within an electronic device. The fluid pump may operate using various physical mechanisms. In some examples, the fluid pump may be implemented as a piezoelectric fluid pump, referring to devices that utilize the piezoelectric effect to move fluids. When a voltage is applied to a piezoelectric material, it deforms, creating a pumping action that moves the fluid through the pump. Piezoelectric pumping may be achieved in several ways, including vibrating diaphragms, peristaltic motion, and flexural plate waves. The fluid pump may be integrated into the housing of the device, attached to an internal surface, or implemented as part of a modular thermal management subsystem. The fluid pump may have any suitable size. In some examples, the fluid pump may be implemented as a piezoelectric micropump having a thickness of between 0.5mm to 1.0mm. In some embodiments, the fluid pump may operate continuously, intermittently, and/or based at least in part on temperature-based control signals. The size, power consumption, and operating characteristics of the fluid pump may be selected based on the cooling requirements, available space, and overall design constraints of the electronic device. In some examples, use of a piezoelectric micropump may beneficially enable thermal management without significantly increasing device bulk, weight, or cost.

The fluid pump may be powered and controlled in any suitable way. For instance, in some examples, circuitry used to power and control the fluid pump may be integrated into the PCB of the computing device. The fluid pump may be communicatively coupled with the PCB in any suitable way, such as via a flexible printed circuit, conductive pads, spring clips, pogo pins, wires, etc. In some examples, piezoelectric fluid pumps may be controlled using a relatively high voltage sinusoidal or square wave. In one non-limiting arrangement, this may be achieved using a series of direct current (DC) boost converters to convert a 5V signal to a 24V signal, and convert the 24V signal to a 125V signal. The 5V signal may in some cases be drawn from an internal regulated voltage rail, such as a 5V supply derived from the device’s battery. The 125V signal may then be supplied to an H-bridge inverter, which outputs a signal useable to drive the fluid pump. In some examples, any or all of these components may be combined together into an integrated circuit, which receives a 5V signal and outputs a 24-50V square or sinusoidal wave. This approach may beneficially enable compact and efficient generation of the high-voltage drive signals required by the fluid pump without necessitating additional external power supplies or voltage sources.

By activating the fluid pump, cooling fluid may be circulated through the plurality of fluid channels, thereby facilitating heat distribution across the device housing component. This is schematically illustrated with respect to FIGS. 2B and 2C. Specifically, FIG. 2B shows a cross-sectional view of aspects of computing device 202, including device housing component 200. A fluid channel 204 is shown on an interior-facing surface of the device housing component, along with fluid pump 208. Additionally, electronic device 202 includes a PCB 210, and a processing component 212 communicatively coupled with the PCB. The processing component is generating heat 214 during operation, which causes heating of the device housing component. As discussed above, portions of the device housing component that are relatively closer to the processing component are heated to a higher temperature, as indicated by the shading patterns shown with device housing component 200. In the example of FIG. 2B, the fluid pump is not active and thus does not contribute to heat distribution across the device housing component.

By contrast, in the scenario depicted in FIG. 2C, the fluid pump has been activated to cause circulation of the cooling fluid in the fluid channel. This in turn facilitates heat distribution across the device housing component. This has the result of reducing the thermal gradient across the device housing component, thereby mitigating localized hot spots that may otherwise occur in proximity to the processing component and/or other heat-generating elements. In FIG. 2C, the temperature of the portion of the device housing component proximate to the processing component is reduced relative to the scenario depicted in FIG. 2B, as thermal energy is absorbed by the cooling fluid and distributed across the surface area of the device housing component as the fluid is circulated. By promoting a more uniform temperature profile across the housing, the circulating cooling fluid enhances the overall thermal performance of the device and helps maintain operating temperatures of internal components and external housing temperatures within desired thresholds. In some embodiments, this uniformity in thermal distribution may beneficially reduce thermal stress on mechanical structures, extend the lifespan of temperature-sensitive components, and/or improve the user experience by limiting areas of excessive surface warmth during device operation.

The fluid pump may be activated at any suitable time and based at least in part on any suitable condition. In some examples, the fluid pump may be activated by default any time the electronic device is powered on. In some examples, the fluid pump may be activated manually by a user – e.g., such as by enabling a “device cooling” mode to make the device more comfortable to handle. In some examples, the fluid pump may be activated automatically based at least in part on a measured temperature of the electronic device exceeding a temperature threshold. For instance, in FIGS. 2B and 2C, the computing device includes a temperature sensor 216 configured to measure the temperature in the interior of the computing device. Thus, the fluid pump may in some cases be activated based at least in part on a temperature output by temperature sensor 216 exceeding a threshold. As discussed above, a computing device may have any suitable number of temperature sensors, each of which may have any suitable position on or within the computing device. Furthermore, activity of the fluid pump may be controlled based on any or all of the temperature measurements from the device’s temperature sensors, and/or an estimated temperature of an exterior device hotspot that is derived from the temperature measurements. This can beneficially contribute to power savings while still facilitating thermal management, by only activating the fluid pump when it would have a significant effect in redistributing heat throughout the device housing component.

Furthermore, in some examples, the activity of the fluid pump may be dynamically controlled based on changes in the measured temperature. For instance, the flow rate of the fluid pump may be proportional to the temperature of the computing device. In such embodiments, a control circuit or processing unit may receive temperature data from one or more temperature sensors positioned within the device, and may adjust the operational parameters of the fluid pump accordingly. For example, as the temperature increases beyond a threshold, the control circuit may increase the driving voltage or duty cycle applied to the fluid pump to increase fluid circulation. Conversely, as the temperature decreases or stabilizes within an acceptable range, the control circuit may reduce or suspend operation of the fluid pump to conserve power. This dynamic control scheme beneficially allows the cooling system to respond adaptively to varying thermal loads, thereby improving thermal efficiency while reducing unnecessary power consumption.

Circulation of the cooling fluid enables distribution of heat throughout the device housing component because the plurality of fluid channels are thermally coupled with the device housing component. The specific nature of the relationship between the fluid channels and the device housing component may vary depending on the implementation. In the example of FIGS. 2A-2C, the fluid channels are separate structures from the device housing component, and are affixed to the interior-facing surface of the device housing component using a bonding layer 218. The bonding layer may take the form of any suitable thermally conductive adhesive, film, or interface material configured to promote efficient thermal transfer between the fluid channels and the housing component while providing mechanical attachment. The fluid channels themselves may be constructed from any suitable material. For instance, they may take the form of conduits formed from suitable metals and/or composite materials, which are then attached to the device housing component via the bonding layer.

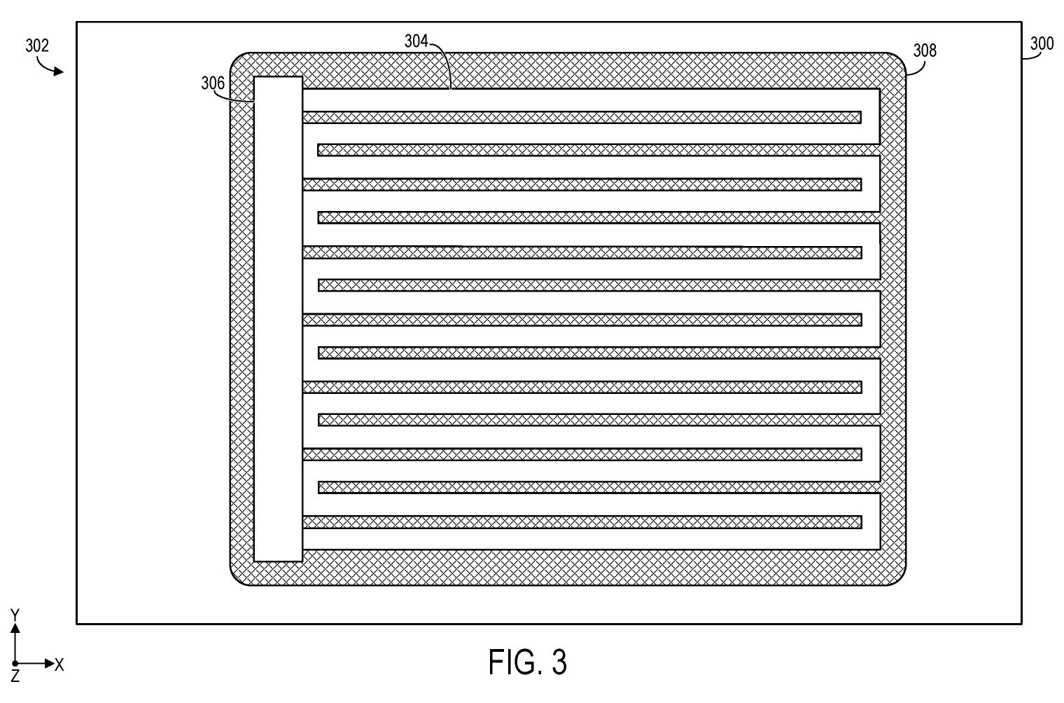

In other embodiments, the fluid channels and device housing component may have another suitable relationship that thermally couples the fluid channels with the device housing component. In one example scenario, the fluid channels may be formed in a flexible or semi-rigid film that conforms to the shape of the housing surface. This arrangement is schematically illustrated with respect to FIG. 3, showing another example device housing component 300 of an electronic device 302. A plurality of fluid channels 304 are thermally coupled with the device housing component, and a fluid pump 306 is configured to circulate cooling fluid throughout the plurality of fluid channels. In this example, the plurality of fluid channels are formed in a film layer 308, which is affixed to the interior-facing surface of the device housing component.

This arrangement may beneficially enable the integration of the fluid channels with device housing components having curved or otherwise irregular geometries. The film layer may be applied using lamination, pressure-sensitive adhesives, heat-activated bonding, and/or other suitable attachment techniques. Use of such a film layer may beneficially enable modular assembly of the thermal management system – e.g., enabling the fluid channel structure to be pre-fabricated and installed as a subassembly during device manufacturing. The film layer itself may be constructed from any suitable materials – e.g., suitable polymers and/or metals.

In other examples, the fluid channels may be formed in the device housing component itself. For instance, the fluid channels may be formed using a subtractive manufacturing technique, in which CNC machining or another suitable technique is used to remove material from the device housing component and thereby form the fluid channels. In other words, in some examples, the plurality of fluid channels may be formed in the device housing component using CNC manufacturing. Alternatively, the device housing component itself may be constructed using an additive manufacturing technique (e.g., such as 3D printing) to form the device housing component with a desired geometry, such that the fluid channels are formed in the device housing component.

These manufacturing techniques may beneficially enable a high degree of design flexibility and allow the channel geometry to be tailored to the thermal distribution requirements of the specific device architecture. Subtractive approaches such as CNC machining provide tight dimensional tolerances, enabling precise control over channel depth, width, and placement, which may be beneficial for optimizing fluid flow characteristics and thermal coupling. Additive manufacturing, by contrast, allows for the integration of complex internal channel networks that may be difficult or impossible to fabricate using subtractive machining. This can facilitate more efficient routing of cooling fluid and support lightweight structural designs.

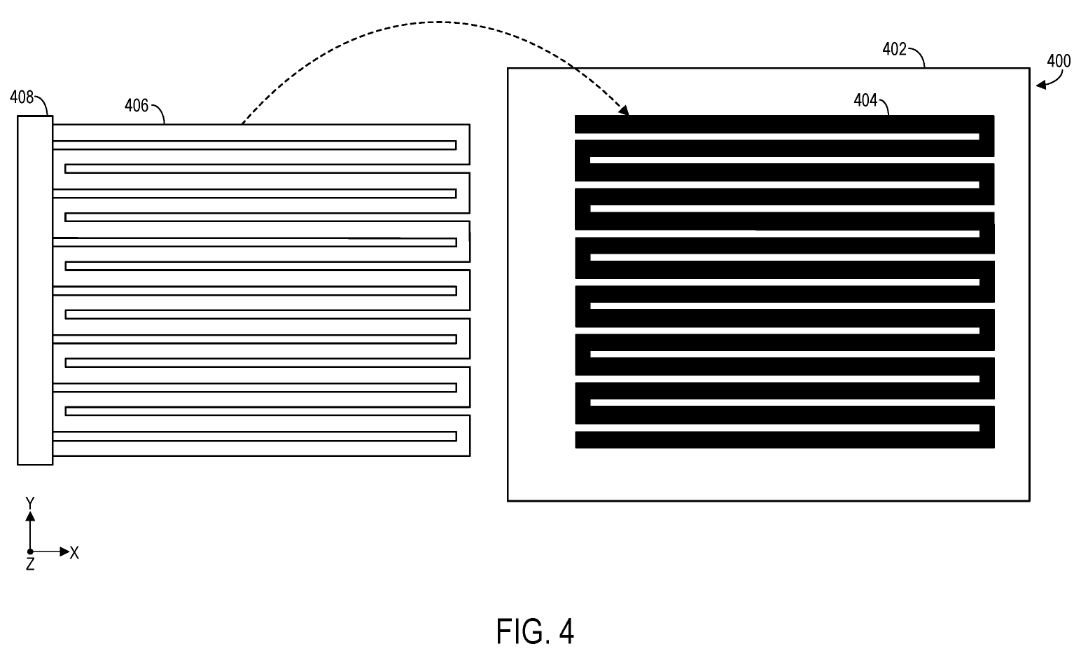

In such cases, where the fluid channels are formed in the device housing component, the fluid channels may be sealed in any suitable way. In some examples, the computing device may include a plurality of sealed fluid conduits that are embedded in the fluid channels, such that the cooling fluid is circulated through the plurality of fluid conduits. This arrangement is schematically illustrated with respect to FIG. 4, showing another example device housing component 400 of a computing device 402. In this example, a plurality of fluid channels 404 are formed in the device housing component itself – e.g., via suitable subtractive or additive manufacturing techniques. A separate plurality of fluid conduits 406 may then be embedded within the fluid channels, and cooling fluid may be circulated within the fluid channels via a fluid pump 408.

The fluid conduits 406 may be formed from flexible or rigid tubing composed of thermally stable and chemically resistant materials, such as suitable polymers and/or metals. The conduits may be positioned within the channels using any suitable attachment method, including adhesive bonding, press-fit engagement, mechanical retention features, etc. In some embodiments, the conduits may be pre-formed to match the routing of the channels, while in other implementations, the conduits may be shaped during the assembly process. This arrangement may beneficially provide a more controlled fluid path and may allow for improved sealing, repairability, and/or modularity of the thermal management system.

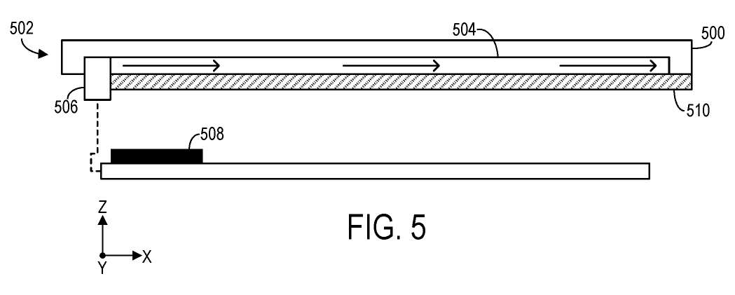

Alternatively, in cases where the fluid channels are formed in the device housing component, the computing system may include a fluid sealing layer that is affixed to an interior-facing surface of the device housing component to enclose the plurality of fluid channels. This arrangement is schematically illustrated with respect to FIG. 5, showing a cross-sectional view of another example device housing component 500 of a computing device 502. In FIG. 5, the computing device includes a fluid channel 504, and a fluid pump 506 configured to circulate cooling fluid through the fluid channel. In this manner, heat produced by a processing component 508 may be distributed throughout the device housing component.

In this example, however, the fluid channel is formed in the device housing component itself, through a suitable subtractive or additive manufacturing technique as discussed above. As such, the computing device additionally includes a fluid sealing layer 510 that serves to seal the fluid channel, and therefore contain the cooling fluid within the fluid channel. The fluid sealing layer may be formed from any suitable material that is impermeable to the cooling fluid. Suitable materials for the sealing layer may include thermally conductive polymers, metallic foils, elastomeric membranes, etc. The sealing layer may be applied using adhesive bonding, thermal lamination, ultrasonic welding, and/or other appropriate joining techniques to ensure a robust seal. This approach may beneficially reduce the bulk of the computing device, by forming the fluid channels within the device housing component itself rather than adding the channels in an additional layer that contributes to device thickness. Similarly, this approach may simplify assembly of the computing device and improve thermal coupling efficiency, as the fluid channels are formed directly in the device housing component.

The present disclosure has primarily focused on cases in which the plurality of fluid channels are formed on an interior-facing surface of the device’s exterior housing, which serves as the barrier between the device interior and the external environment. However, as discussed above, in some cases, fluid channels may be thermally coupled with other device housing components in addition to, or instead of, an external housing. For instance, in some examples, the fluid channels may be thermally coupled with a device housing component taking the form of a mid-frame of the computing device. The mid-frame may be positioned internally within the device and may serve as a central structural element supporting the computing device’s display, PCB, battery, and/or other subsystems. In such embodiments, the mid-frame may also function as a thermal management surface by receiving heat from one or more processing components and distributing it via fluid flow through the thermally coupled fluid channels.

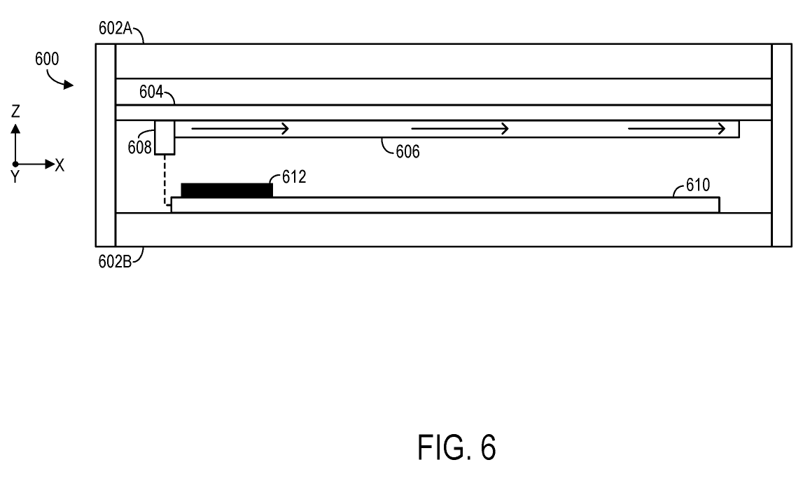

This arrangement is schematically depicted with respect to FIG. 6, showing a cross-sectional view of another example computing device 600. In this example, the computing device includes a first external housing component 602A and a second external housing component 602B, which both serve to separate the interior of the computing device from the exterior environment. Additionally, the computing device includes a mid-frame 604 within the device interior. A fluid channel 606 is thermally coupled with the device mid-frame, such that a fluid pump 608 causes circulation of cooling fluid within the fluid channel. The computing device additionally includes a PCB 610, and a processing component 612 that generates heat during operation. Thus, heat generated by the processing component may be absorbed by cooling fluid within the fluid channel 606, and this heat may be distributed throughout the device mid-frame via circulation of the cooling fluid.

Because the mid-frame typically spans a large internal area and is often positioned in close proximity to high-power components, coupling fluid channels to the mid-frame may provide efficient thermal interception and redistribution within the device interior, before heat reaches the external housing. This may allow the device to maintain lower external surface temperatures while still effectively managing internal heat. Additionally, incorporating fluid channels into or onto the mid-frame may enable multi-layer thermal architectures in which heat is spread through a combination of internal and external housing components, improving thermal performance without significantly increasing device thickness or compromising spatial layout. In some cases, the mid-frame may further act as a thermal intermediary, channeling heat from internal components to one or more external housing surfaces via embedded fluid networks or thermally conductive pathways.

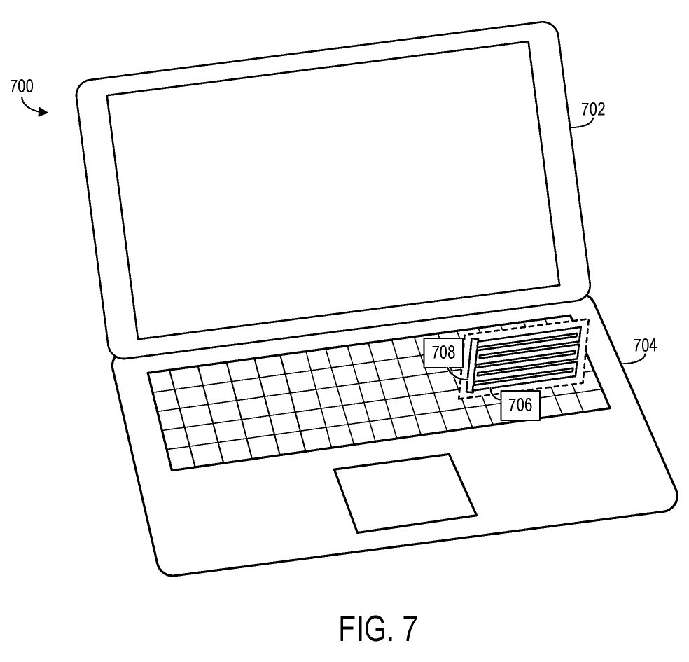

FIG. 7 schematically shows another example scenario, in which the plurality of fluid channels are integrated into an input device that is communicatively coupled with a computing device. Specifically, FIG. 7 schematically shows an example computing device 700, including a display portion 702 and an input portion 704. In this scenario, the display portion functions as a tablet computer that can be used on its own, separately from the input portion. It will be understood, however, that similar arrangements may be used for computing devices that do not include separable components – e.g., such as conventional laptop computer form factors. Regardless, either or both of the display portion and the input portion may include fluid channels for thermal management, as discussed above. In the example of FIG. 7, the input portion includes a plurality of fluid channels 706, and a corresponding fluid pump 708 configured to circulate cooling fluid through the plurality of fluid channels. In this manner, a thermal gradient across the surface of the input portion may be reduced, to thereby reduce the temperature of any localized hot spots on the input portion. This may beneficially enhance user comfort while handling the input portion.

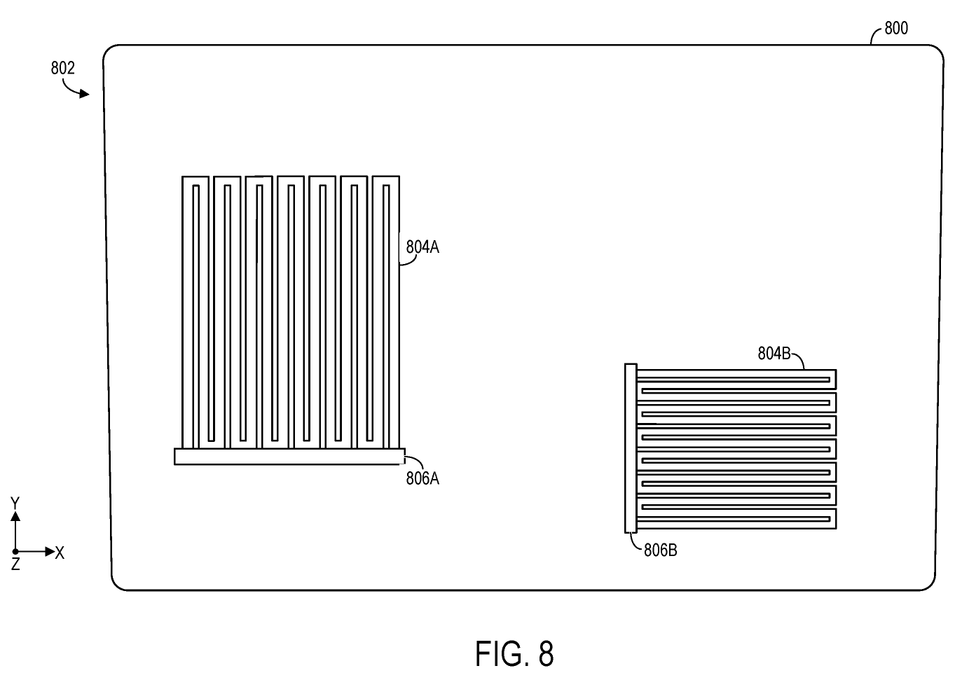

FIG. 8 schematically shows an example scenario in which the computing device includes two or more separate, independent sets of fluid channels. Specifically, FIG. 8 schematically shows another example device housing component 800 of a computing device 802. The computing device includes a first plurality of fluid channels 804A, along with a corresponding fluid pump 806A configured to circulate cooling fluid within the cooling channels. Additionally, in this example, the computing device includes a second plurality of fluid channels 804B thermally coupled with the device housing component, and a second fluid pump 806B configured to circulate cooling fluid through the second plurality of fluid channels.

In some examples, these different sets of fluid channels may be used for different portions of the device housing component at which hot spots tend to form. For instance, the different sets of fluid channels may be placed at positions on the device housing component that are proximate to different processing components that generate substantial heat during operation. Furthermore, the activity of the fluid pumps 806A and 806B may in some cases be controlled based at least in part on measured temperature readings, as discussed above. In some examples, the two fluid pumps may be controlled separately – e.g., based on readings from different corresponding temperature sensors. In other words, in one example scenario, each of the fluid pumps 806A and 806B may be associated with different corresponding temperature sensors and may be activated to facilitate thermal distribution based at least in part on measured temperature readings that exceed predetermined thresholds. The size, shape, placement, orientation composition, and/or other properties of these different respective sets of fluid channels may differ in any suitable way.

The present disclosure has thus far primarily focused on redistributing heat throughout the device housing component to reduce the thermal gradient – e.g., to reduce the difference between hotter portions of the housing and cooler portions of the housing – without necessarily cooling the housing overall. For instance, the techniques described herein may beneficially be used with passive cooling implementations, in which device bulk is reduced by omitting active cooling components such as fans or radiators. However, it will be understood that the arrangements described herein can also be applied in scenarios where the computing device includes active cooling components. For instance, circulation of cooling fluid through the fluid channels can be used to transfer heat away from a localized hot spot and towards the active cooling system, which can beneficially improve dissipation of heat from the computing device.

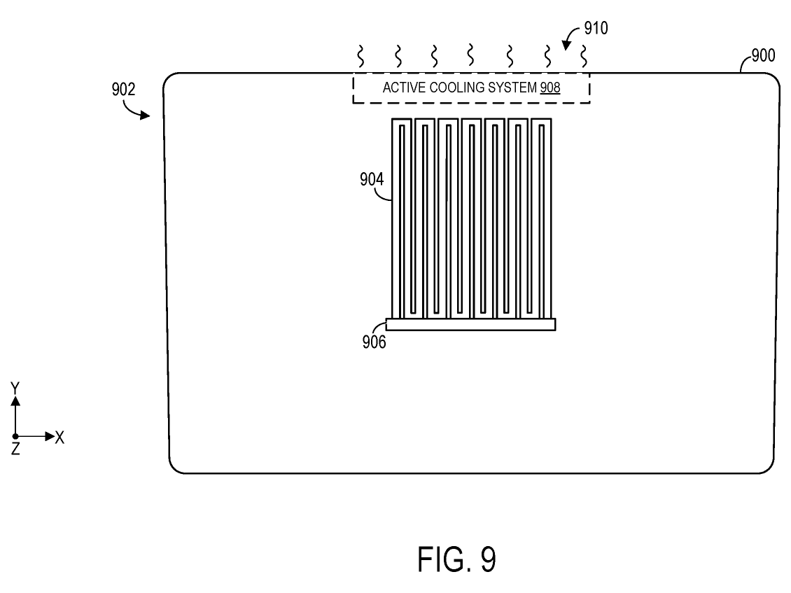

This scenario is schematically depicted with respect to FIG. 9, showing another example device housing component 900 of a computing device 902. A plurality of fluid channels 904 are thermally coupled with the device housing component, and a fluid pump 906 is configured to circulate fluid through the plurality of fluid channels. The computing device additionally includes an active cooling system 908, which is configured to dissipate heat 910 from the computing device into an external environment. Circulation of the cooling fluid within the fluid channels can beneficially serve to distribute heat away from internal processing components of the computing device, toward the active cooling system, thereby beneficially facilitating a reduction in overall device temperature. In other words, in this example, the computing device includes an active cooling system configured to dissipate heat from the computing device, and circulation of the cooling fluid facilitates heat transfer from the processing component to the active cooling system.

Any suitable active cooling system may be used. As used herein, the term "active cooling system" refers to a thermal management system that includes one or more components configured to dissipate heat by actively inducing fluid movement or phase change, typically through mechanical or electrical means. Examples of active cooling systems include, but are not limited to, systems incorporating fans, blowers, thermoelectric coolers (e.g., Peltier devices), liquid cooling loops with circulating pumps, and/or vapor chamber assemblies with active heat spreading mechanisms. An active cooling system may operate continuously or based at least in part on detected thermal conditions, and may be controlled by the device’s processing unit or thermal management circuitry.

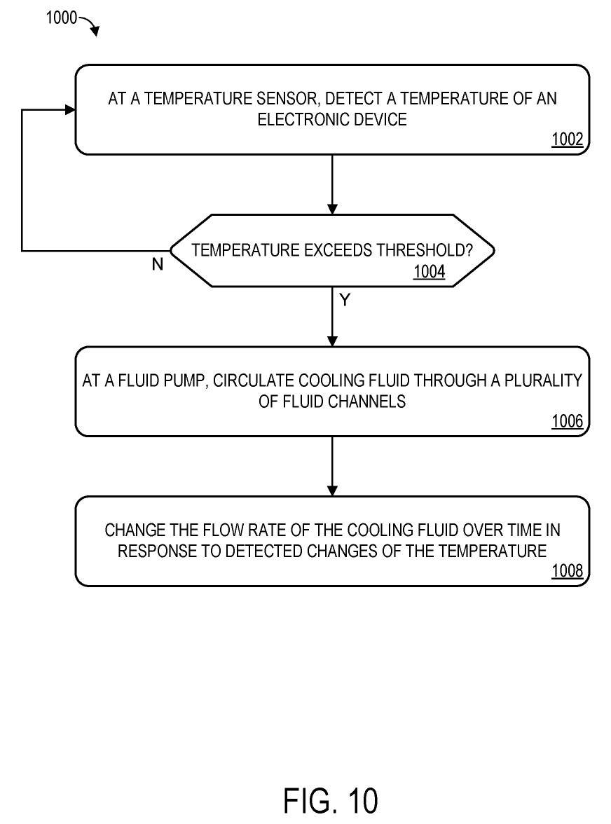

As discussed above, in some examples, activity of the fluid pump may be controlled based at least in part on a temperature measurement output by a temperature sensor of the computing device. To this end, FIG. 10 illustrates an example method 1000 for heat distribution in a computing device. Steps of method 1000 may be initiated, terminated, and/or repeated at any suitable time and based at least in part on any suitable condition. One or more steps of method 1000 may be performed by a suitable computing system of one or more computing devices. A computing device implementing steps of method 1000 may have any suitable capabilities, hardware configuration, and form factor. In some examples, method 1000 may be performed by computing system 1100 described below with respect to FIG. 11.

At 1002, method 1000 includes, at a temperature sensor of a computing device, measuring a temperature of the computing device. The computing device includes a processing component that generates heat during operation, and a device housing component proximate to the processing component, such that the device housing component is heated by the processing component. As discussed above, a computing device may include any suitable number of temperature sensors, each of which may have any suitable position on or within the computing device. Activity of a fluid pump may be controlled based on measurements from any or all such temperature sensors, and/or based on an estimated external surface temperature of the computing device that is derived the temperature measurements.

At 1004, method 1000 includes determining whether the temperature exceeds a predetermined threshold. If NO, method 1000 returns to method 1002, and continues monitoring the temperature of the computing device. If YES, method 1000 proceeds to 1006, which includes, at a fluid pump, circulating cooling fluid through a plurality of fluid channels thermally coupled with the device housing component, such that the cooling fluid facilitates heat distribution across the device housing component. In other words, based at least in part on determining that the temperature of the computing device (e.g., a temperature of a specific portion of the computing device) exceeds a threshold, the fluid pump is activated, which can facilitate heat distribution across the device housing component.

At 1008, method 1000 includes, at the fluid pump, changing the flow rate of the cooling fluid over time based at least in part on detected changes of the temperature of the computing device. For instance, as the temperature of the computing device increases or decreases (e.g., based on workload, battery level, and/or external environmental conditions), the flow rate of the cooling fluid can be dynamically increased or decreased. This can beneficially facilitate thermal management of the computing device without consuming unnecessary power. In the event that the temperature of the computing device falls below a threshold, then the fluid pump may in some cases be deactivated, to thereby beneficially conserve electrical power of the computing device when less thermal regulation is warranted.

The methods and processes described herein may be tied to a computing system of one or more computing devices. In particular, such methods and processes may be implemented as an executable computer-application program, a network-accessible computing service, an application-programming interface (API), a library, or a combination of the above and/or other compute resources.

FIG. 11 schematically shows a simplified representation of a computing system 1100 configured to provide any to all of the compute functionality described herein. Computing system 1100 may take the form of one or more personal computers, network-accessible server computers, tablet computers, home-entertainment computers, gaming devices, mobile computing devices, mobile communication devices (e.g., smart phone), virtual/augmented/mixed reality computing devices, wearable computing devices, Internet of Things (IoT) devices, embedded computing devices, and/or other computing devices.

Computing system 1100 includes a logic subsystem 1102 and a storage subsystem 1104. Computing system 1100 may optionally include a display subsystem 1106, input subsystem 1108, communication subsystem 1110, and/or other subsystems not shown in FIG. 11.

Logic subsystem 1102 includes one or more physical devices configured to execute instructions. For example, the logic subsystem may be configured to execute instructions that are part of one or more applications, services, or other logical constructs. The logic subsystem may include one or more hardware processors configured to execute software instructions. Additionally, or alternatively, the logic subsystem may include one or more hardware or firmware devices configured to execute hardware or firmware instructions. Processors of the logic subsystem may be single-core or multi-core, and the instructions executed thereon may be configured for sequential, parallel, and/or distributed processing. Individual components of the logic subsystem optionally may be distributed among two or more separate devices, which may be remotely located and/or configured for coordinated processing. Aspects of the logic subsystem may be virtualized and executed by remotely-accessible, networked computing devices configured in a cloud-computing configuration.

Storage subsystem 1104 includes one or more physical devices configured to temporarily and/or permanently hold computer information such as data and instructions executable by the logic subsystem. When the storage subsystem includes two or more devices, the devices may be collocated and/or remotely located. Storage subsystem 1104 may include volatile, nonvolatile, dynamic, static, read/write, read-only, random-access, sequential-access, location-addressable, file-addressable, and/or content-addressable devices. Storage subsystem 1104 may include removable and/or built-in devices. When the logic subsystem executes instructions, the state of storage subsystem 1104 may be transformed – e.g., to hold different data.

Aspects of logic subsystem 1102 and storage subsystem 1104 may be integrated together into one or more hardware-logic components. Such hardware-logic components may include program- and application-specific integrated circuits (PASIC/ASICs), program- and application-specific standard products (PSSP/ASSPs), system-on-a-chip (SOC), and complex programmable logic devices (CPLDs), for example.

The logic subsystem and the storage subsystem may cooperate to instantiate one or more logic machines. As used herein, the term “machine” is used to collectively refer to the combination of hardware, firmware, software, instructions, and/or any other components cooperating to provide computer functionality. In other words, “machines” are never abstract ideas and always have a tangible form. A machine may be instantiated by a single computing device, or a machine may include two or more sub-components instantiated by two or more different computing devices. In some implementations a machine includes a local component (e.g., software application executed by a computer processor) cooperating with a remote component (e.g., cloud computing service provided by a network of server computers). The software and/or other instructions that give a particular machine its functionality may optionally be saved as one or more unexecuted modules on one or more suitable storage devices.

When included, display subsystem 1106 may be used to present a visual representation of data held by storage subsystem 1104. This visual representation may take the form of a graphical user interface (GUI). Display subsystem 1106 may include one or more display devices utilizing virtually any type of technology. In some implementations, display subsystem may include one or more virtual-, augmented-, or mixed reality displays.

When included, input subsystem 1108 may comprise or interface with one or more input devices. An input device may include a sensor device or a user input device. Examples of user input devices include a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition.

When included, communication subsystem 1110 may be configured to communicatively couple computing system 1100 with one or more other computing devices. Communication subsystem 1110 may include wired and/or wireless communication devices compatible with one or more different communication protocols. The communication subsystem may be configured for communication via personal-, local- and/or wide-area networks.

This disclosure is presented by way of example and with reference to the associated drawing figures. Components, process steps, and other elements that may be substantially the same in one or more of the figures are identified coordinately and are described with minimal repetition. It will be noted, however, that elements identified coordinately may also differ to some degree. It will be further noted that some figures may be schematic and not drawn to scale. The various drawing scales, aspect ratios, and numbers of components shown in the figures may be purposely distorted to make certain features or relationships easier to see.

In an example, a computing device comprises: a processing component that generates heat during operation; a device housing component proximate to the processing component, such that the device housing component is heated by the processing component; a plurality of fluid channels thermally coupled with the device housing component; and a fluid pump configured to circulate cooling fluid through the plurality of fluid channels in the device housing component, such that the cooling fluid facilitates heat distribution across the device housing component. In this example or any other example, the computing device further comprises one or more temperature sensors configured to measure a temperature of the computing device, and wherein the fluid pump is activated to cause circulation of the cooling fluid based at least in part on the temperature exceeding a temperature threshold. In this example or any other example, a flow rate of the fluid pump is proportional to the temperature of the computing device. In this example or any other example, the computing device further comprises an active cooling system configured to dissipate heat from the computing device, and wherein circulation of the cooling fluid facilitates heat transfer from the processing component to the active cooling system. In this example or any other example, the computing device further comprises a film layer affixed to an interior-facing surface of the device housing component, and wherein the plurality of fluid channels are formed in the film layer. In this example or any other example, the plurality of fluid channels are formed in the device housing component using CNC (computer numerical control) manufacturing. In this example or any other example, the plurality of fluid channels are formed in the device housing component, and wherein the device housing component is constructed using an additive manufacturing technique. In this example or any other example, the plurality of fluid channels are formed in the device housing component, and wherein a plurality of fluid conduits are embedded in the plurality of fluid channels, such that the cooling fluid is circulated through the plurality of fluid conduits. In this example or any other example, the plurality of fluid channels are formed in the device housing component, and wherein a fluid sealing layer is affixed to an interior-facing surface of the device housing component to enclose the plurality of fluid channels. In this example or any other example, the computing device further comprises a second plurality of fluid channels thermally coupled with the device housing component, and a second fluid pump configured to circulate cooling fluid through the second plurality of fluid channels. In this example or any other example, the fluid pump is a piezoelectric fluid pump. In this example or any other example, the device housing component is an external housing of the computing device. In this example or any other example, the device housing component is a mid-frame of the computing device.

In an example, a computing device comprises: a processing component that generates heat during operation; a device housing component proximate to the processing component, such that the device housing component is heated by the processing component; one or more temperature sensors configured to measure a temperature of the computing device; a plurality of fluid channels thermally coupled with the device housing component; and a fluid pump configured to circulate cooling fluid through the plurality of fluid channels in the device housing component, such that the cooling fluid facilitates heat distribution across the device housing component, wherein the fluid pump is activated to cause circulation of the cooling fluid based at least in part on the temperature exceeding a temperature threshold. In this example or any other example, a flow rate of the fluid pump is proportional to the temperature of the computing device. In this example or any other example, the computing device further comprises an active cooling system configured to dissipate heat from the computing device, and wherein circulation of the cooling fluid facilitates heat transfer from the processing component to the active cooling system. In this example or any other example, the computing device further comprises a second plurality of fluid channels thermally coupled with the device housing component, and a second fluid pump configured to circulate cooling fluid through the second plurality of fluid channels. In this example or any other example, the fluid pump is a piezoelectric fluid pump.

In an example, a method for heat distribution in a computing device comprises: at one or more temperature sensors, measuring a temperature of the computing device, wherein the computing device includes a processing component that generates heat during operation, and a device housing component proximate to the processing component, such that the device housing component is heated by the processing component; based at least in part on the temperature exceeding a temperature threshold, at a fluid pump, circulating cooling fluid through a plurality of fluid channels thermally coupled with the device housing component, such that the cooling fluid facilitates heat distribution across the device housing component; and at the fluid pump, changing a flow rate of the cooling fluid over time based at least in part on detected changes of the temperature of the computing device. In this example or any other example, the fluid pump is a piezoelectric fluid pump.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A computing device, comprising:
a processing component that generates heat during operation;
a device housing component proximate to the processing component, such that the device housing component is heated by the processing component;
a plurality of fluid channels thermally coupled with the device housing component; and
a fluid pump configured to circulate cooling fluid through the plurality of fluid channels in the device housing component, such that the cooling fluid facilitates heat distribution across the device housing component.

2. The computing device of claim 1, further comprising one or more temperature sensors configured to measure a temperature of the computing device, and wherein the fluid pump is activated to cause circulation of the cooling fluid based at least in part on the temperature exceeding a temperature threshold.

3. The computing device of claim 2, wherein a flow rate of the fluid pump is proportional to the temperature of the computing device.

4. The computing device of claim 1, further comprising an active cooling system configured to dissipate heat from the computing device, and wherein circulation of the cooling fluid facilitates heat transfer from the processing component to the active cooling system.

5. The computing device of claim 1, further comprising a film layer affixed to an interior-facing surface of the device housing component, and wherein the plurality of fluid channels are formed in the film layer.

6. The computing device of claim 1, wherein the plurality of fluid channels are formed in the device housing component using CNC (computer numerical control) manufacturing.

7. The computing device of claim 1, wherein the plurality of fluid channels are formed in the device housing component, and wherein the device housing component is constructed using an additive manufacturing technique.

8. The computing device of claim 1, wherein the plurality of fluid channels are formed in the device housing component, and wherein a plurality of fluid conduits are embedded in the plurality of fluid channels, such that the cooling fluid is circulated through the plurality of fluid conduits.

9. The computing device of claim 1, wherein the plurality of fluid channels are formed in the device housing component, and wherein a fluid sealing layer is affixed to an interior-facing surface of the device housing component to enclose the plurality of fluid channels.

10. The computing device of claim 1, further comprising a second plurality of fluid channels thermally coupled with the device housing component, and a second fluid pump configured to circulate cooling fluid through the second plurality of fluid channels.

11. The computing device of claim 1, wherein the fluid pump is a piezoelectric fluid pump.

12. The computing device of claim 1, wherein the device housing component is an external housing of the computing device.

13. The computing device of claim 1, wherein the device housing component is a mid-frame of the computing device.

14. A computing device, comprising:
a processing component that generates heat during operation;
a device housing component proximate to the processing component, such that the device housing component is heated by the processing component;
one or more temperature sensors configured to measure a temperature of the computing device;
a plurality of fluid channels thermally coupled with the device housing component; and
a fluid pump configured to circulate cooling fluid through the plurality of fluid channels in the device housing component, such that the cooling fluid facilitates heat distribution across the device housing component, wherein the fluid pump is activated to cause circulation of the cooling fluid based at least in part on the temperature exceeding a temperature threshold.

15. The computing device of claim 14, wherein a flow rate of the fluid pump is proportional to the temperature of the computing device.

16. The computing device of claim 14, further comprising an active cooling system configured to dissipate heat from the computing device, and wherein circulation of the cooling fluid facilitates heat transfer from the processing component to the active cooling system.

17. The computing device of claim 14, further comprising a second plurality of fluid channels thermally coupled with the device housing component, and a second fluid pump configured to circulate cooling fluid through the second plurality of fluid channels.

18. The computing device of claim 14, wherein the fluid pump is a piezoelectric fluid pump.

19. A method for heat distribution in a computing device, the method comprising:
at one or more temperature sensors, measuring a temperature of the computing device, wherein the computing device includes a processing component that generates heat during operation, and a device housing component proximate to the processing component, such that the device housing component is heated by the processing component;
based at least in part on the temperature exceeding a temperature threshold, at a fluid pump, circulating cooling fluid through a plurality of fluid channels thermally coupled with the device housing component, such that the cooling fluid facilitates heat distribution across the device housing component; and
at the fluid pump, changing a flow rate of the cooling fluid over time based at least in part on detected changes of the temperature of the computing device.

20. The method of claim 19, wherein the fluid pump is a piezoelectric fluid pump.
